(19) United States
(12) Patent Application Publication
(10) Pub. No.: US 2024/0071728 A1
(43) Pub. Date: Feb. 29, 2024

(54) SUBSTRATE PROCESSING METHOD AND PLASMA PROCESSING APPARATUS

(71) Applicant: Tokyo Electron Limited, Tokyo (JP)

(72) Inventors: Takanori BANSE, Miyagi (JP); Shota YOSHIMURA, Miyagi (JP); Hsinkai WANG, Miyagi (JP)

(73) Assignee: Tokyo Electron Limited, Tokyo (JP)

(21) Appl. No.: 18/240,403

(22) Filed: Aug. 31, 2023

(30) Foreign Application Priority Data
Aug. 31, 2022 (JP) 2022-137721

(51) Int. Cl. H01J 37/32; H01L 21/311

(52) U.S. Cl. CPC H01J 37/32449; H01J 37/32174; H01L 21/31116; H01J 2237/334

(57) ABSTRACT

A substrate processing method (a) provides a substrate on a substrate support unit provided in a chamber, and (b) supplies a processing gas into the chamber. The substrate includes a first region formed of a material including silicon and a second region formed of a material different from the material of the first region. The processing gas includes tungsten and a component for etching the first region. The substrate processing method (c) repeats a cycle while the processing gas is supplied into the chamber at (c). The cycle includes first to third processes. The power level of a source radio-frequency power in the first process is higher than the power level of the source radio-frequency power in each of the second and third processes.

### CROSS-REFERENCE TO RELATED APPLICATION

This application is based on and claims priority from Japanese Patent Application No. 2022-137721, filed on Aug. 31, 2022, with the Japan Patent Office, the disclosure of which is incorporated herein in its entirety by reference.

### TECHNICAL FIELD

The present disclosure relates to a substrate processing method and a plasma processing apparatus.

### BACKGROUND

Japanese Patent Laid-Open Publication No. 2016-157793 discloses a method of selectively etching a first region of a substrate with respect to a second region of the substrate by using plasma formed from a processing gas. The first region is formed of silicon oxide, and the second region is formed of silicon nitride. The processing gas includes fluorocarbon.

### SUMMARY

An embodiment provides a substrate processing method. The substrate processing method includes (a) providing a substrate on a substrate support unit in a chamber of a plasma processing apparatus. The substrate includes a first region formed of a material including silicon and a second region formed of a material different from the material of the first region. The substrate processing method further includes (b) supplying a processing gas into the chamber. The processing gas includes tungsten and a component for etching the first region. The substrate processing method further includes (c) repeating a cycle while (b) is being performed. The cycle includes (c1) setting a power level of a source radio-frequency power for generating plasma from the processing gas in the chamber to a level L_{S1}, and a level of an electrical bias supplied to the substrate support unit to a level L_{B1}. The cycle further includes (c2) after (c1), setting the power level of the source radio-frequency power to a level L_{S2}, and the level of the electrical bias to a level L_{B2}. The cycle further includes (c3) after (c2), setting the power level of the source radio-frequency power to a level L_{S3}, and the level of the electrical bias to a level L_{B3}. The level L_{S1} is higher than the levels L_{S2} and L_{S3}. The level L_{B3} is higher than the level L_{B1}. The level L_{B2} is higher than zero.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an example of a configuration of a plasma processing system.

FIG. 2 is a view illustrating an example of a configuration of a capacitively coupled plasma processing apparatus.

FIG. 3 is a flowchart of a substrate processing method according to an embodiment.

FIG. 4 is a partially enlarged cross-sectional view illustrating an example of a substrate to which the method of FIG. 3 is applicable.

FIG. 5 is a partially enlarged cross-sectional view illustrating an example of a substrate obtained from a process corresponding to the method of FIG. 3.

FIG. 6 is a partially enlarged cross-sectional view illustrating an example of a substrate obtained from a process corresponding to the method of FIG. 3.

FIG. 7 is a timing chart of an example related to a cycle in the method of FIG. 3.

FIG. 8 is a timing chart of an example related to a cycle in the method of FIG. 3.

FIG. 9 is a timing chart of an example related to a cycle in the method of FIG. 3.

FIG. 10 is a flowchart of a substrate processing method according to another embodiment.

FIG. 11A is a partially enlarged cross-sectional view of an example of a substrate to which the method of FIG. 10 is applicable, and FIGS. 11B to 11E are each a partially enlarged cross-sectional view of an example of a substrate obtained from a process corresponding to the method of FIG. 10.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Various embodiments will be described below.

An embodiment provides a substrate processing method. The substrate processing method includes (a) providing a substrate on a substrate support unit in a chamber of a plasma processing apparatus. The substrate includes a first region formed of a material including silicon and a second region formed of a material different from the material of the first region. The substrate processing method further includes (b) supplying a processing gas into the chamber. The processing gas includes tungsten and a component for etching the first region. The substrate processing method further includes (c) repeating a cycle while (b) is being performed. The cycle includes (c1) setting a power level of a source radio-frequency power for generating plasma from the processing gas in the chamber to a level L_{S1}, and a level of an electrical bias supplied to the substrate support unit to a level L_{B1}. The cycle further includes (c2) after (c1), setting the power level of the source radio-frequency power to a level L_{S2}, and the level of the electrical bias to a level L_{B2}. The cycle further includes (c3) after (c2), setting the power level of the source radio-frequency power to a level L_{S3}, and the level of the electrical bias to a level L_{B3}. The level L_{S1} is higher than the levels L_{S2} and L_{S3}. The level L_{B3} is higher than the level L_{B1}. The level L_{B2} is higher than zero.

In (c1) of the substrate processing method above, the source radio-frequency power having a relatively high power level is provided so that a deposit containing tungsten is formed on the second region. In (c2), ions are attracted to the deposit by the electrical bias having the level L_{B2} so that the deposit is modified. In (c3), the electrical bias having a relatively high level is provided so that ions with a high energy are attracted to the substrate, and thus, the first region is etched. In (c3), the second region is protected by the modified deposit. Thus, according to the substrate processing method above, the etching selectivity is improved.

Another embodiment provides a plasma processing apparatus. The plasma processing apparatus includes a chamber, a substrate support unit, a gas supply unit, a radio-frequency power supply, a bias power supply, and a control unit. The substrate support unit is provided in the chamber. The gas supply unit supplies a processing gas into the chamber. The processing gas includes tungsten and a component for etching a material including silicon. The radio-frequency power supply supplies a source radio-frequency power for generating plasma from the processing gas in the chamber. The bias power supply is electrically coupled to the substrate support unit. In a state where the substrate is disposed on the substrate support unit, the control unit controls the gas supply unit, the radio-frequency power supply, and the bias power supply to perform (b) and (c). In (b), the processing gas is supplied from the gas supply unit into the chamber. The (c) is performed while (b) is being performed. In (c), a cycle is repeated. The cycle includes (c1) setting a power level of the source radio-frequency power to a level L_{S1}, and a level of an electrical bias supplied from the bias power supply to the substrate support unit to a level L_{B1}. The cycle includes (c2) after (el), setting the power level of the source radio-frequency power to a level L_{S2}, and the level of the electrical bias to a level L_{B2}. The cycle includes (c3) after (c2), setting the power level of the source radio-frequency power to a level L_{S3}, and the level of the electrical bias to a level L_{B3}. The level L_{S1} is higher than the levels L_{S2} and L_{S3}. The level L_{B3} is higher than the level L_{B1}. The level L_{B2} is higher than zero.

Hereinafter, the various embodiments will be described in detail with reference to the drawings. In the respective drawings, similar or corresponding portions will be denoted by the same reference numerals.

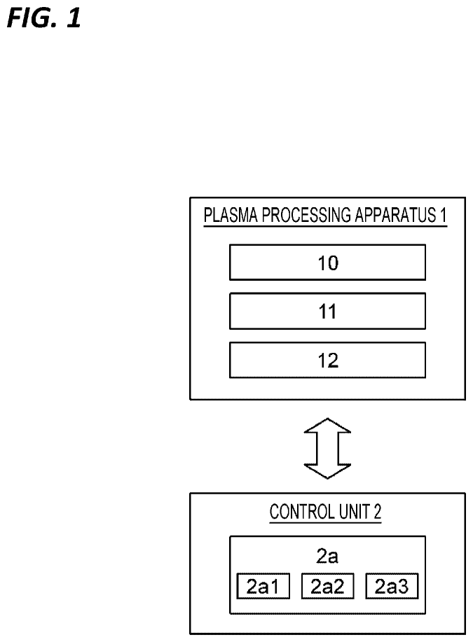

FIG. 1 is a view illustrating an example of a configuration of a plasma processing system. In an embodiment, the plasma processing system includes a plasma processing apparatus 1 and a control unit 2. The plasma processing system is an example of a substrate processing system, and the plasma processing apparatus 1 is an example of a substrate processing apparatus. The plasma processing apparatus 1 includes a plasma processing chamber 10, a substrate support unit 11, and a plasma generation unit 12. The plasma processing chamber 10 has a plasma processing space. Further, the plasma processing chamber 10 includes at least one gas supply port for supplying at least one processing gas into the plasma processing space, and at least one gas discharge port for discharging a gas from the plasma processing space. The gas supply port is connected to a gas supply unit 20 to be described later, and the gas discharge port is connected to an exhaust system 40 to be described later. The substrate support unit 11 is disposed in the plasma processing space, and has a substrate support surface for supporting a substrate thereon.

The plasma generation unit 12 is configured to generate plasma from at least one processing gas supplied into the plasma processing space. The plasma formed in the plasma processing space may be, for example, capacitively coupled plasma (CCP), inductively coupled plasma (ICP), electron-cyclotron-resonance (ECR) plasma, helicon wave plasma (HWP), or surface wave plasma (SWP).

The control unit 2 processes computer-executable commands to cause the plasma processing apparatus 1 to perform various processes described herein. The control unit 2 may be configured to control each component of the plasma processing apparatus 1 to perform the various processes described herein. In an embodiment, a portion of the control unit 2 or the entire control unit 2 may be included in the plasma processing apparatus 1. The control unit 2 may include a processing unit 2a1, a storage unit 2a2, and a communication interface 2a3. The control unit 2 is implemented by, for example, a computer 2a. The processing unit 2a1 may be configured to perform various control operations by reading programs from the storage unit 2a2 and executing the read programs. The programs may be stored in the storage unit 2a2 in advance, or may be acquired via a medium when necessary. The acquired programs are stored in the storage unit 2a2, and read from the storage unit 2a2 to be executed by the processing unit 2a1. The medium may be any of various storage media readable by the computer 2a, or may be a communication line connected to the communication interface 2a3. The processing unit 2a1 may be a central processing unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

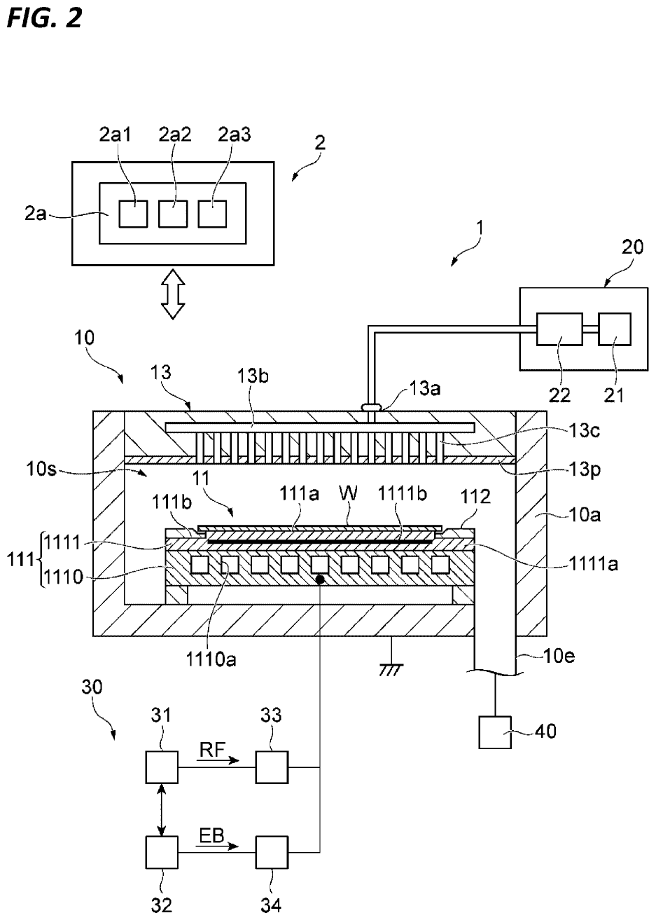

Hereinafter, an example of a configuration of a capacitively coupled plasma processing apparatus, which is an example of the plasma processing apparatus 1, will be described. FIG. 2 is a view illustrating an example of a configuration of the capacitively coupled plasma processing apparatus.

A capacitively coupled plasma processing apparatus 1 includes the plasma processing chamber 10, the gas supply unit 20, a power supply system 30, and the exhaust system 40. Further, the plasma processing apparatus 1 includes a substrate support unit 11 and a gas introduction unit. The gas introduction unit is configured to introduce at least one processing gas into the plasma processing chamber 10. The gas introduction unit includes a shower head 13. The substrate support unit 11 is disposed inside the plasma processing chamber 10. The shower head 13 is disposed above the substrate support unit 11. In an embodiment, the shower head 13 makes up at least a portion of the ceiling of the plasma processing chamber 10. The plasma processing chamber 10 has a plasma processing space 10s defined by the shower head 13, the side wall 10a of the plasma processing chamber 10, and the substrate support unit 11. The plasma processing chamber 10 is grounded. The substrate support unit 11 is electrically insulated from the housing of the plasma processing chamber 10.

The substrate support unit 11 includes a main body 111 and a ring assembly 112. The main body 111 has a central region 111a for supporting a substrate W, and an annular region 111b for supporting the ring assembly 112. A wafer is an example of the substrate W. The annular region 111b of the main body 111 surrounds the central region 111a of the main body 111 in plan view. The substrate W is disposed on the central region 111a of the main body 111, and the ring assembly 112 is disposed on the annular region 111b of the main body 111 to surround the substrate W disposed on the central region 111a of the main body 111. Accordingly, the central region 111a is referred to as the substrate support surface for supporting the substrate W, and the annular region 111b is referred to as a ring support surface for supporting the ring assembly 112.

In an embodiment, the main body 111 includes a base 1110 and an electrostatic chuck 1111. The base 1110 includes a conductive member. The electrostatic chuck 1111 is disposed on the base 1110. The electrostatic chuck 1111 includes a ceramic member 1111a and an electrostatic electrode 1111b disposed inside the ceramic member 1111a. The ceramic member 1111a has the central region 111a. In an embodiment, the ceramic member 1111a also has the annular region 111b. Another member surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member.

The ring assembly 112 includes one or a plurality of annular members. In an embodiment, the one or plurality of annular members include one or a plurality of edge rings and at least one cover ring. The edge ring is formed of a conductive material or an insulating material, and the cover ring is formed of an insulating material.

The substrate support unit 11 may include a temperature adjustment module configured to adjust at least one of the electrostatic chuck 1111, the ring assembly 112, and the substrate to a target temperature. The temperature adjustment module may include a heater, a heat transfer medium, a flow path 1110a, or a combination thereof. A heat transfer fluid such as brine or a gas flows through the flow path 1110a. In an embodiment, the flow path 1110a is formed inside the base 1110, and one or a plurality of heaters is disposed inside the ceramic member 1111a of the electrostatic chuck 1111. The substrate support unit 11 may include a heat transfer gas supply unit configured to supply a heat transfer gas to the gap between the back surface of the substrate W and the central region 111a.

The shower head 13 is configured to introduce at least one processing gas from the gas supply unit 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes at least one upper electrode. The gas introduction unit may include one or a plurality of side gas injectors (SGI) attached to one or a plurality of openings formed in the side wall 10a, in addition to the shower head 13.

The gas supply unit 20 may include at least one gas source 21 and at least one flow rate controller 22. In an embodiment, the gas supply unit 20 is configured to supply at least one processing gas from the corresponding gas source 21 to the shower head 13 via the corresponding flow rate controller 22. Each flow rate controller 22 may include, for example, a mass flow controller or a pressure-controlled flow rate controller. The gas supply unit 20 may further include at least one flow rate modulation device that modulates or pulses the flow rate of at least one processing gas.

The exhaust system 40 may be connected to a gas discharge port 10e provided at, for example, the bottom of the plasma processing chamber 10. The exhaust system 40 may include a pressure regulation valve and a vacuum pump. The pressure in the plasma processing space 10s is regulated by the pressure regulation valve. The vacuum pump may include a turbo molecular pump, a dry pump, or a combination thereof.

The power supply system 30 includes a radio-frequency power supply 31 and a bias power supply 32. The radio-frequency power supply 31 makes up the plasma generation unit 12 of an embodiment. The radio-frequency power supply 31 is configured to generate a source radio-frequency power RF. The source radio-frequency power RF has a source frequency f_{RF}. That is, the source radio-frequency power RF has a sinusoidal waveform, of which frequency is the source frequency f_{RF}. The source frequency f_{RF} may be a frequency in the range of 13 MHz to 100 MHz. The radio-frequency power supply 31 is electrically connected to a radio-frequency electrode via a matching unit 33, and is configured to supply the source radio-frequency power RF to the radio-frequency electrode. The radio-frequency electrode may be provided inside the substrate support unit 11. The radio-frequency electrode may be at least one electrode provided inside the conductive member of the base 1110 or the ceramic member 1111a. Alternatively, the radio-frequency electrode may be an upper electrode. When the source radio-frequency power RF is supplied to the radio-frequency electrode, plasma is generated from a gas in the chamber 10.

The matching unit 33 has a variable impedance. The variable impedance of the matching unit 33 is set to reduce the reflection of the source radio-frequency power RF from a load. The matching unit 33 may be controlled by, for example, the control unit 2.

The bias power supply 32 is electrically coupled to the substrate support unit 11. The bias power supply 32 is electrically connected to a bias electrode inside the substrate support unit 11, and is configured to supply an electrical bias EB to the bias electrode. The bias electrode may be at least one electrode provided in the conductive member of the base 1110 or the ceramic member 1111a. The bias electrode may be common with the radio-frequency electrode. When the electrical bias EB is supplied to the bias electrode, ions from the plasma are attracted into the substrate W.

The electrical bias EB has a waveform cycle, and is periodically supplied to the bias electrode from the bias power supply 32. The waveform cycle of the electrical bias EB is defined by a bias frequency. The bias frequency is, for example, 100 kHz or more and 50 MHz or less. The time length of the waveform cycle of the electrical bias EB is the reciprocal of the bias frequency.

The electrical bias EB may be a bias radio-frequency power having the bias frequency. That is, the electrical bias EB may have a sinusoidal waveform, of which frequency is the bias frequency. In this case, the bias power supply 32 is electrically connected to the bias electrode via a matching unit 34. The variable impedance of the matching unit 34 is set to reduce the reflection of the bias radio-frequency power from a load.

The electrical bias EB may include a voltage pulse. The voltage pulse is applied to the bias electrode within the waveform cycle. The voltage pulse is periodically applied to the bias electrode at an interval of the same time length as the time length of the waveform cycle. The waveform of the voltage pulse may be a square wave, a triangular wave, or any other waveforms. The polarity of the voltage of the voltage pulse is set to cause a difference in potential between the substrate W and plasma, thereby attracting ions from the plasma into the substrate W. The voltage pulse may be a negative voltage pulse or a negative DC voltage pulse. When the electrical bias EB includes the voltage pulse, the plasma processing apparatus 1 may not include the matching unit 34.

The level of the electrical bias EB may be described herein below. When the electrical bias EB is the bias radio-frequency power, the level of the electrical bias EB is the power level of the bias radio-frequency power. When the electrical bias EB includes the voltage pulse, the level of the electrical bias EB is the absolute value of the negative voltage level of the voltage pulse.

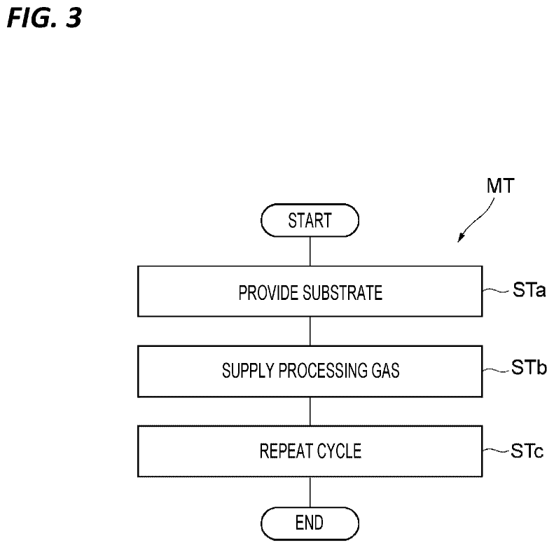

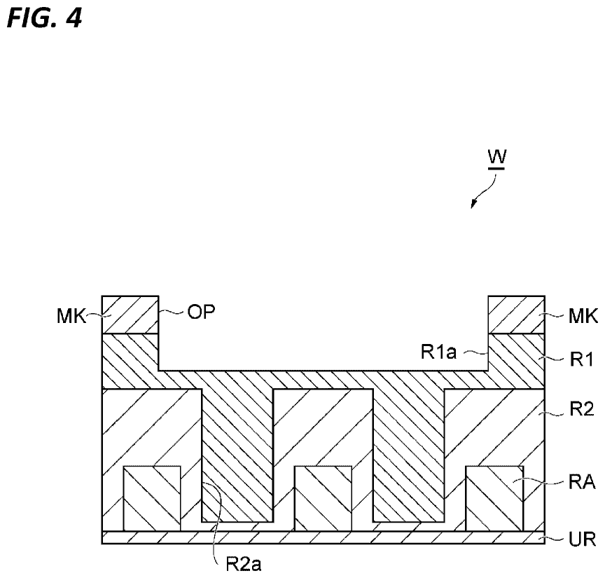

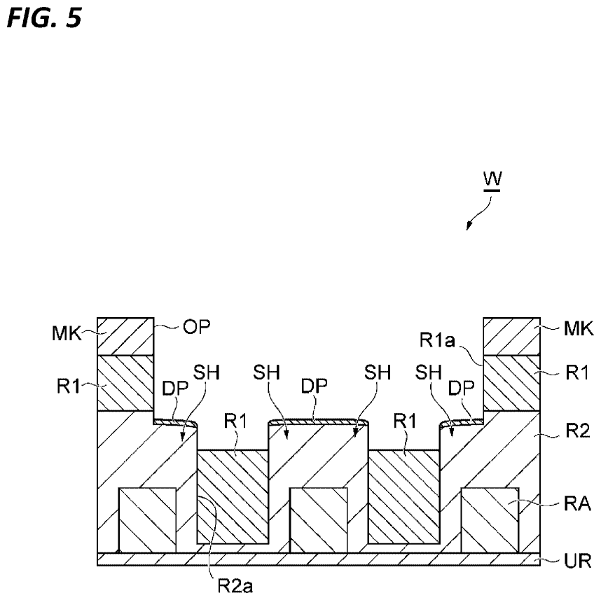

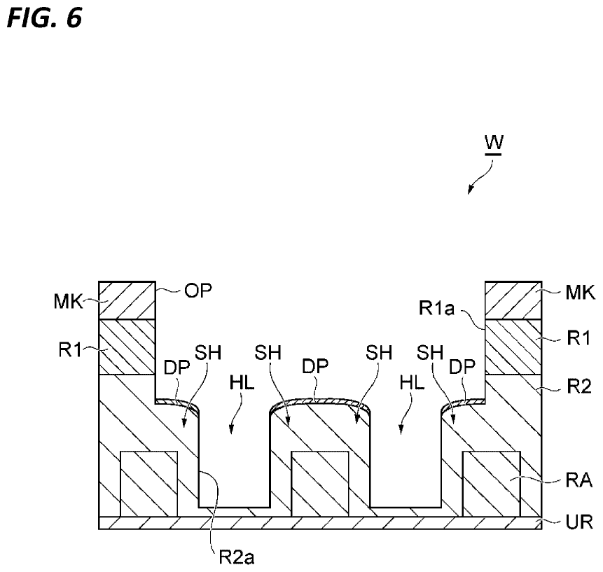

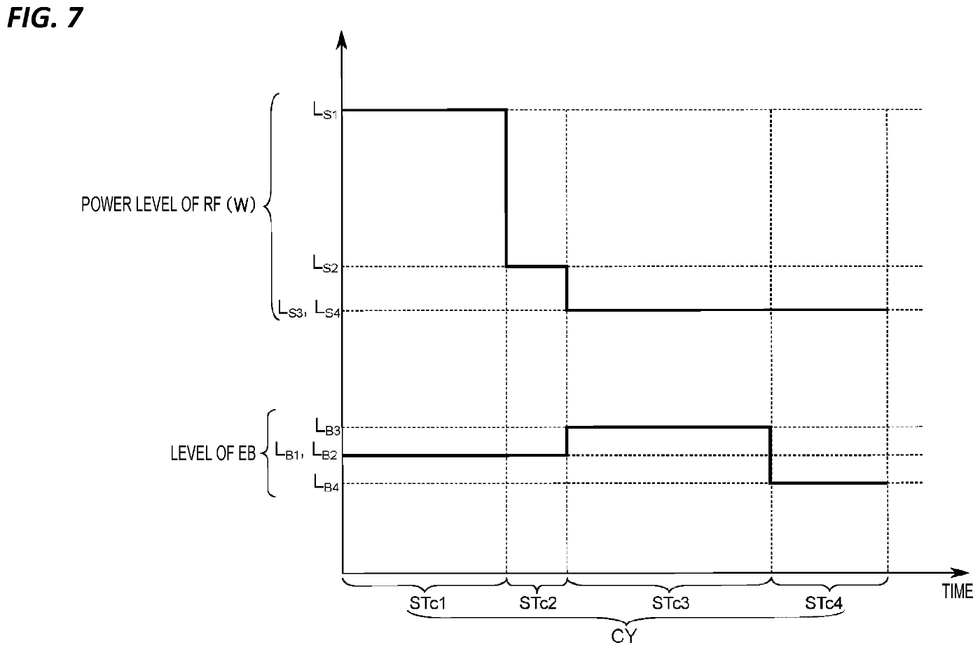

FIGS. 3 to 9 will be referred to hereinafter. FIG. 3 is a flowchart of a substrate processing method according to an embodiment. FIG. 4 is a partially enlarged cross-sectional view illustrating an example of a substrate to which the method of FIG. 3 is applicable. FIGS. 5 and 6 are each a partially enlarged cross-sectional view illustrating an example of a substrate obtained from a process corresponding to the method of FIG. 3. FIGS. 7 to 9 are each a timing chart of an example related to a cycle in the method of FIG. 3.

The substrate processing method illustrated in FIG. 3 (hereinafter, referred to as a “method MT”) may be performed by the plasma processing apparatus 1. The method MT may be applied to the substrate W. The substrate W includes a first region and a second region. The first region is formed of a material including silicon. The second region is formed of a material different from the material of the first region. The material of the first region may be silicon oxide. The material of the second region may be silicon nitride, silicon germanium, tungsten carbide, or silicon carbide.

As illustrated in FIG. 4, in an embodiment, the substrate W includes a first region R1 and a second region R2. The second region R2 provides at least one recess R2a. The second region R2 may provide a plurality of recesses R2a. Each recess R2a may be a recess for forming a contact hole. The first region R1 may be embedded in the recess R2a. The first region R1 may be formed to cover the second region R2.

In an embodiment, the first region R1 includes silicon and oxygen. The first region R1 may include silicon oxide (SiOₓ). The first region R1 may have a recess R1a. The recess R1a has a larger width than the width of the recess R2a.

In an embodiment, the second region R2 includes silicon and nitrogen. The first region R1 may include silicon nitride (SiNₓ). The second region R2 may include a first portion including silicon nitride (SiNₓ) and a second portion including silicon carbide (SiC). In this case, the first portion may provide the recess R2a.

The substrate W may further include an underlying region UR and a plurality of raised regions RA. The plurality of raised regions RA are formed on the underlying region UR. The underlying region UR and at least the plurality of raised regions RA are covered by the second region R2. The underlying region UR may include silicon. The recess R2a of the second region R2 is located between two adjacent raised regions RA. Each raised region RA may form a gate region of a transistor.

The substrate W may further include a mask MK. The mask MK is provided on the first region R1. The mask MK may include metal or silicon. The mask MK provides an opening OP. The opening OP corresponds to the recess R1a of the first region R1.

As illustrated in FIG. 3, the method MT includes steps STa, STb, and STc. In step STa, the substrate W is provided on the substrate support unit 11. The substrate W is disposed on the electrostatic chuck 1111, and is held by the electrostatic chuck 1111.

Step STb is performed after step STa. In step STb, a processing gas is supplied into the chamber 10. The processing gas includes tungsten and a component for etching the first region R1. The processing gas may include tungsten halide gas or a tungsten-containing gas as the gas component containing tungsten. The tungsten halide gas may include at least one of tungsten hexafluoride (WF₆) gas, tungsten hexabromide (WBr₆) gas, tungsten hexachloride (WCl₆) gas, and WF₅Cl gas. The tungsten-containing gas may include hexacarbonyl tungsten (W(CO)₆) gas.

The processing gas may further include at least one of a fluorine-containing gas, an oxygen-containing gas, and a hydrogen-containing gas. The fluorine-containing gas may include at least one of fluorocarbon gas and hydrofluorocarbon gas. The fluorocarbon (CₓF_{y}) gas may include at least one of CF₄ gas, C₃F₈ gas, C₄F₈ gas, and C₄F₆ gas. The hydrofluorocarbon (CₓH_{y}F_{z}) gas may include at least one of CH₂F₂ gas, CHF₃ gas, and CH₃F gas. The oxygen-containing gas may include at least one of O₂ gas, CO gas, and CO₂ gas. The hydrogen-containing gas may include, for example, H₂ gas. The processing gas may include, for example, a noble gas such as argon.

In step STb, the control unit 2 controls the gas supply unit 20 to supply the processing gas into the chamber 10. In step STb, the control unit 2 controls the exhaust system 40 to set the pressure in the chamber 10 to a specified pressure.

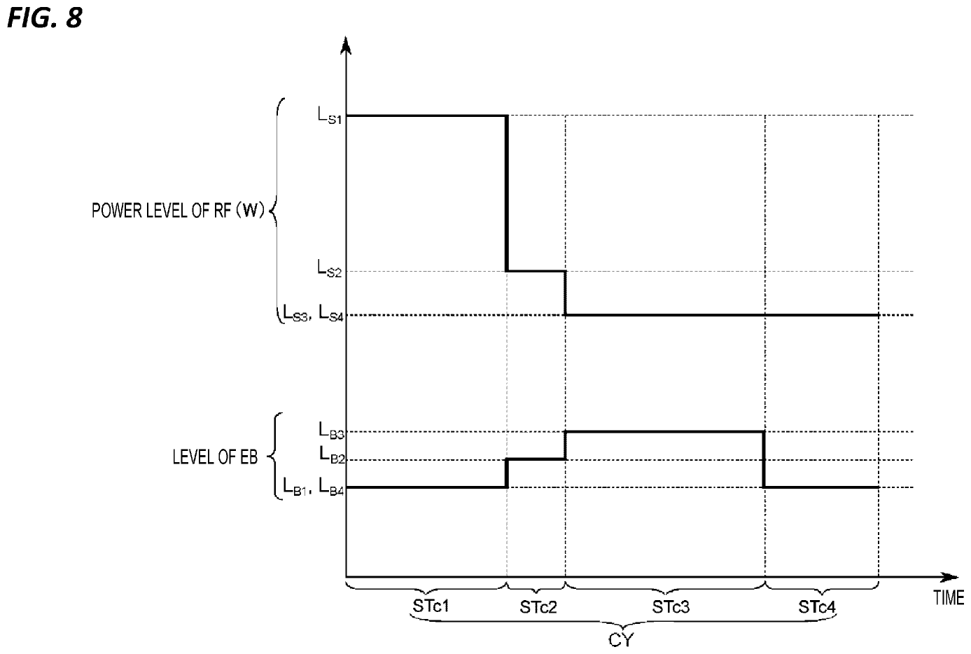

Step STc is performed during the time period when step STb is being performed. In step STc, a cycle CY is repeated. The cycle CY is repeated at least twice during step STc. As illustrated in FIGS. 7 and 8, the cycle CY includes steps STc1 to STc3. The cycle CY may further include step STc4. In each of steps STc1 to STc4, the control unit 2 controls the radio-frequency power supply 31 and the bias power supply 32, to set the power level of the source radio-frequency power RF and the level of the electrical bias EB.

In step STc1, the power level of the source radio-frequency power RF is set to a level L_{S1}, and the level of the electrical bias EB is set to a level L_{B1}. Step STc2 is performed after or immediately after step STc1. In step STc2, the power level of the source radio-frequency power RF is set to a level L_{S2}, and the level of the electrical bias EB is set to a level L_{B2}. Step STc3 is performed after or immediately after step STc2. In step STc3, the power level of the source radio-frequency power RF is set to a level L_{S3}, and the level of the electrical bias EB is set to a level L_{B3}. Step STc4 is performed after or immediately after step STc3. In step STc4, the power level of the source radio-frequency power RF is set to a level L_{S4}, and the level of the electrical bias EB is set to a level L_{B4}.

As illustrated in FIGS. 7 to 9, the level L_{S1} is higher than the levels L_{S2} and L_{S3}. The level L_{B3} is higher than the level L_{B1}. Further, as illustrated in FIGS. 7 and 8, the level L_{B2} is higher than zero. The level L_{B2} may be lower than the level L_{B3}.

In step STc1, the source radio-frequency power RF having a relatively high power level is supplied, so that a deposit DP including tungsten is formed on the second region R2. In step STc2, ions are attracted from plasma to the deposit DP by the electrical bias EB having the level L_{B2}, so that the deposit DP is modified. In step STc3, the electrical bias EB having a relatively high level is supplied, so that ions with a high energy are attracted from the plasma to the substrate W, and thus, the first region R1 is etched. As a result, a recess HL is formed in the first region R1. In step STc3, the second region R2 is protected by the modified deposit DP as illustrated in FIGS. 5 and 6. Thus, according to the method MT, the etching selectivity improves. That is, the etching selectivity of the first region R1 improves, relative to the etching of the second region R2.

In the method MT, since the second region R2 is protected by the deposit DP, the etching of the second region R2 including a shoulder SH is suppressed. Further, in the method MT, the second region R2 may be protected, even when the thickness of the deposit DP is small. As a result, the first region R1 may be etched while suppressing a clogging caused by the deposit DP, so that the recess HL may be formed. Further, it is possible to suppress the width of the recess HL from decreasing along with the increase in depth of the recess.

In the method MT, each of the levels L_{S4} and L_{B4} may be zero or about zero, i.e., substantially zero. That is, plasma may not be generated during step STc4. In step STc4, by-products generated in the etching of step STc3 are discharged from the inside of the chamber 10.

In an embodiment, the time length of step STc3 in the cycle CY may be longer than the time length of step STc2 in the cycle CY. In any case where the cycle CY includes or does not include step STc4, the proportion of the time length of step STc2 in the time length of the cycle CY may be less than 20%. Further, in any case where the cycle CY includes or does not include step STc4, the proportion of the time length of step STc3 in the time length of the cycle CY may be more than 25% or may be 70% or less. Further, in any case where the cycle CY includes or does not include step STc4, the proportion of the time length of step STc1 in the time length of the cycle CY may be more than 10% or may be less than 75%.

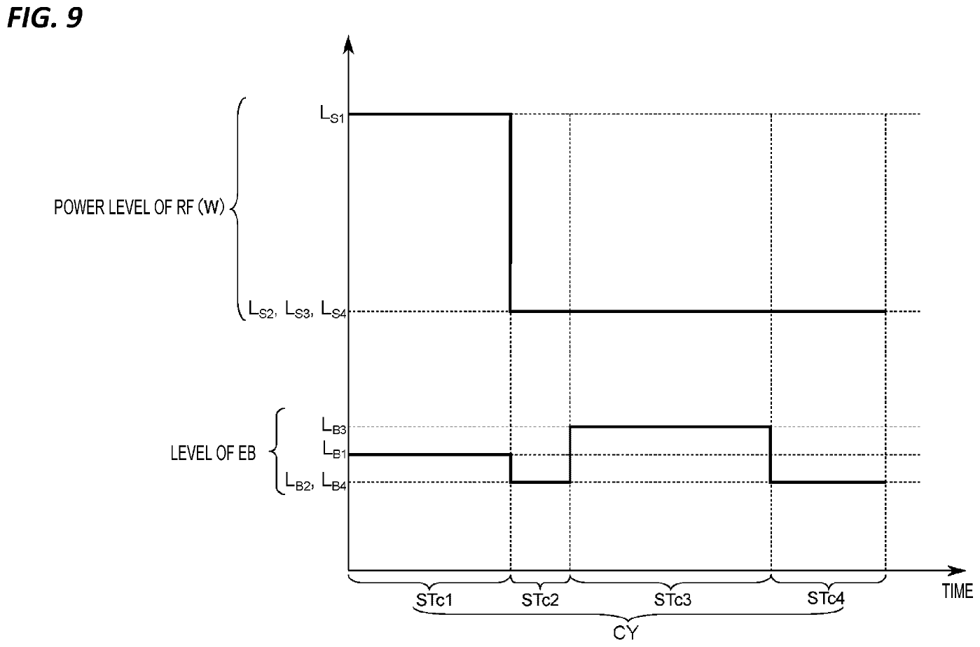

As illustrated in FIGS. 7 and 8, the level L_{S2} may be higher than zero. As illustrated in FIG. 9, the level L_{S2} may be zero or about zero, i.e., substantially zero. As illustrated in FIGS. 7 to 9, the level L_{S3} may be zero or about zero, i.e., substantially zero. When the level L_{S3} is substantially zero, ions and/or radicals are easily attracted vertically into the recess HL.

As illustrated in FIGS. 7 and 9, the level L_{B1} may be higher than zero. As the level of the electrical bias EB in step STc1 is high, the tungsten-containing component may be attracted into the deeper part of the recess HL, so that the deposit DP may be formed even in the deeper part of the substrate W. As illustrated in FIG. 8, the level L_{B1} may be zero or about zero, i.e., substantially zero. When the level of the electrical bias EB in step STc1 is substantially zero, the deposit DP may be formed in a relatively large amount on the upper portion of the substrate W.

In an embodiment, as illustrated in FIG. 7, the levels L_{B1} and L_{B2} may be substantially equal to each other. Further, in an embodiment, when the electrical bias EB is the bias radio-frequency power, the level L_{B1} may be less than 20% of the level L_{S1}.

As illustrated in FIG. 9, the level L_{B2} may be zero or about zero. In this case, ions and radicals are generated in step STc1; in step STc2, the electron temperature and the ion temperature in the plasma are lowered, suppressing the horizontal migration of active species; and the ions are attracted into the substrate W in step STc3. As a result, in step STc3, the expansion of the incident angle of the ions with respect to the vertical incident angle to the substrate W is suppressed.

In an embodiment, the temperature of the substrate support unit 11 during step STc may be 30° C. or higher and 250° C. or lower.

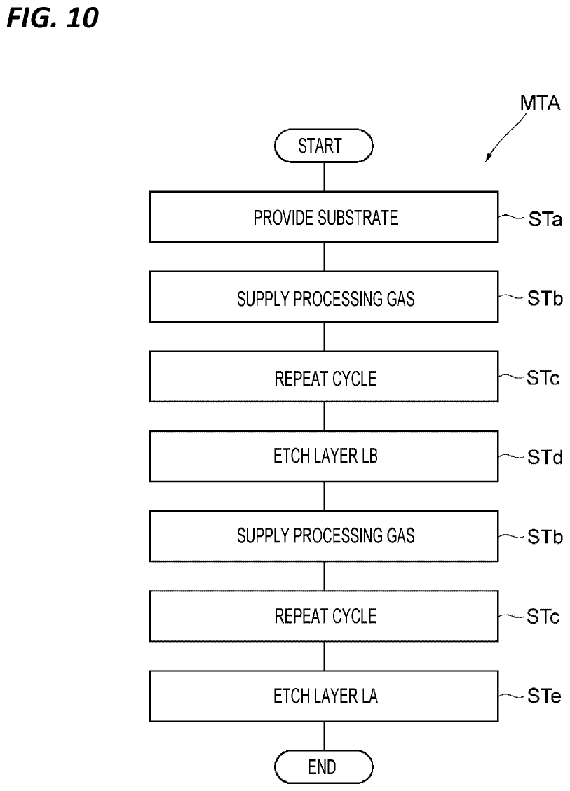

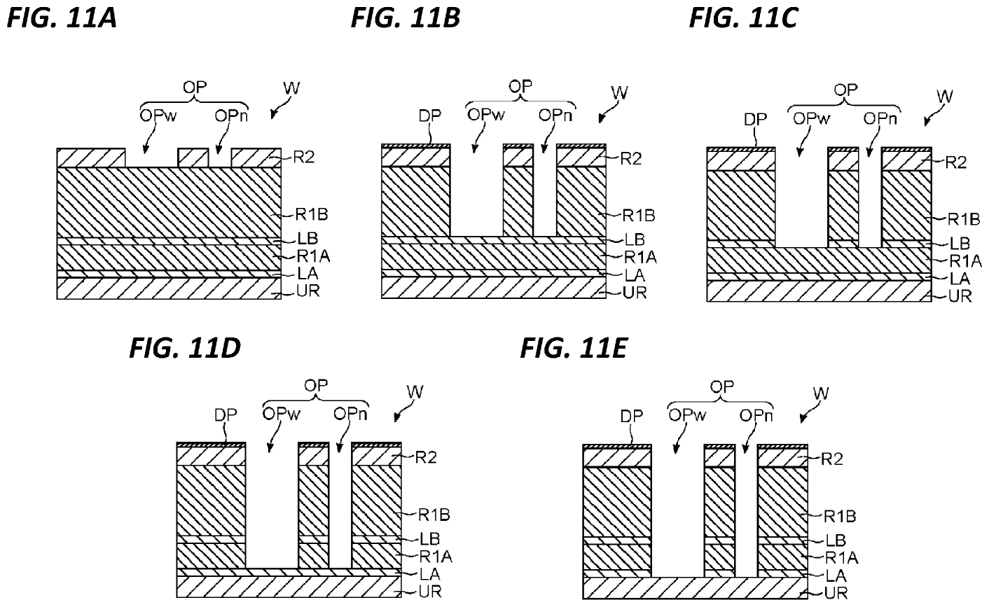

Hereinafter, FIGS. 10 and 11A to 11E will be referred to. FIG. 10 is a flowchart of a substrate processing method according to another embodiment. FIG. 11A is a partially enlarged cross-sectional view of an example of a substrate to which the method of FIG. 10 is applicable, and FIGS. 11B to 11E are each a partially enlarged cross-sectional view of an example of a substrate obtained from a process corresponding to the method of FIG. 10.

A substrate processing method illustrated in FIG. 10 (hereinafter, referred to as a “method MTA”) may be applied to a substrate W illustrated in FIG. 11A. The substrate W illustrated in FIG. 11A includes an underlying region UR, a layer LA, a first region R1A, a layer LB, a first region R1B, and a second region R2.

The underlying region UR is formed of, for example, a silicon-containing film such as silicon germanium. The layer LA is formed on the underlying region UR. The layer LA is formed of, for example, silicon nitride. The first region R1A is formed on the layer LA. The first region R1A is formed of, for example, silicon oxide. The layer LB is formed on the first region R1A. The layer LB is formed of, for example, silicon nitride. The first region R1B is formed on the layer LB. The first region R1B is formed of, for example, silicon oxide. The second region R2 is formed on the first region R1B. The second region R2 is formed of, for example, tungsten carbide. The second region R2 functions as a mask, and may provide a plurality of openings OP. The plurality of openings OP include openings OPw and OPn, and partially expose the first region R1B. The width of the opening OPw is larger than the width of the opening OPn.

In step STa of the method MTA, the substrate W is provided on the substrate support unit 11, as in step STa of the method MT.

Next, in the method MTA, step STb is performed. In step STb of the method MTA, a processing gas is supplied into the chamber 10, as in step STb of the method MT. The processing gas used in the method MTA is the same as the processing gas used in step STb of the method MT.

In the method MTA, step STc is performed in the time period when step STb is being performed. In step STc of the method MTA, the cycle CY is repeated, as in step STc of the method MT. As a result, the first region R1B is etched, as illustrated in FIG. 11B.

Next, in the method MTA, step STd is performed. In step STd, the layer LB is etched. A selected etching gas is used to etch the layer LB. The etching gas may include hydrofluorocarbon gas. In step STd, plasma is generated from the etching gas, and the layer LB is etched by active species from the plasma (see, e.g., FIG. 11C). In step STd, the control unit 2 may control the gas supply unit 20, the exhaust system 40, the radio-frequency power supply 31, and the bias power supply 32.

Next, in the method MTA, steps STb and STc are performed again. As a result, the first region R1A is etched, as illustrated in FIG. 11D.

Next, in the method MTA, step STe is performed. In step STe, the layer LA is etched. A selected etching gas is used to etch the layer LA. The etching gas may include hydrofluorocarbon gas. In step STe, plasma is generated from the etching gas, and the layer LB is etched by active species from the plasma (see, e.g., FIG. 11E). In step STe, the control unit 2 may control the gas supply unit 20, the exhaust system 40, the radio-frequency power supply 31, and the bias power supply 32.

In the method MTA, a deposit DP is formed on the second region R2 during steps STc1 and STc2 of the cycle CY. The deposit DP protects the second region R2 during the etching in steps STc3, STd, and STe of the cycle CY. According to the method MTA, thus, the etching of the second region R2 is suppressed. Further, in the method MTA, the second region R2 may be protected, even when the thickness of the deposit DP is small. As a result, the etching of the region, within the substrate W, exposed from the opening OP may be progressed while suppressing a clogging caused by the deposit DP. Further, the width of the recess formed in the substrate W to be continuous to the opening OP may be suppressed from decreasing as the depth of the recess increases. Further, the etching of the substrate W may be progressed while suppressing the reduction and the expansion of the width of each of the recesses formed in the substrate W to be continuous to the openings OPw and OPn, respectively.

While the various embodiments have been described, various additions, omissions, substitutions, and changes may be made without being limited to the above-described embodiments. Further, elements of different embodiments may be combined with each other to form another embodiment.

For example, the methods MT and MTA may be performed using a different plasma processing apparatus from the plasma processing apparatus 1.

Here, the various embodiments included in the present disclosure are described in [E1] through [E12] below.

[E1] A substrate processing method including:
(a) providing a substrate on a substrate support unit in a chamber of a plasma processing apparatus, the substrate including a first region formed of a material including silicon and a second region formed of a material different from the material of the first region;
(b) supplying a processing gas into the chamber, the processing gas including tungsten and a component for etching the first region; and
(c) repeating a cycle while (b) is being performed,
wherein the cycle includes
   (c1) setting a power level of a source radio-frequency power for generating plasma from the processing gas in the chamber to a level L_{S1}, and a level of an electrical bias supplied to the substrate support unit to a level L_{B1},
   (c2) after (c1), setting the power level of the source radio-frequency power to a level L_{S2}, and the level of the electrical bias to a level L_{B2}, and
   (c3) after (c2), setting the power level of the source radio-frequency power to a level L_{S3}, and the level of the electrical bias to a level L_{B3},
wherein the level L_{S1} is higher than the levels L_{S2} and L_{S3},
wherein the level L_{B3} is higher than the level L_{B1}, and
wherein the level L_{B2} is higher than zero.

[E2] The substrate processing method according to [E1], wherein the level L_{S2} is higher than zero.

[E3] The substrate processing method according to [E1] or [E2], wherein the level L_{S3} is substantially zero.

[E4] The substrate processing method according to any one of [E1] to [E3], wherein the level L_{B2} is lower than the level L_{B3}.

[E5] The substrate processing method according to any one of [E1] to [E4], wherein the level L_{B1} is substantially zero.

[E6] The substrate processing method according to any one of [E1] to [E5], wherein in the cycle, a time length of (c3) is longer than a time length of (c2).

[E7] The substrate processing method according to any one of [E1] to [E6], wherein the processing gas includes tungsten halide gas or tungsten hexafluoride gas.

[E8] The substrate processing method according to [E7], wherein the processing gas further includes at least one of a fluorine-containing gas, an oxygen-containing gas, and a hydrogen-containing gas.

[E9] The substrate processing method according to any one of [E1] to [E8], wherein the material of the first region is silicon oxide.

[E10] The substrate processing method according to any one of [E1] to [E9], wherein the material of the second region is silicon nitride, silicon germanium, tungsten carbide, or silicon carbide.

[E11] The substrate processing method according to any one of [E1] to [E10], wherein the cycle further includes
(c4) after (c3), setting the power level of the source radio-frequency power and the level of the electrical bias to substantially zero.

[E12] A plasma processing apparatus including:
a chamber;
a substrate support unit provided in the chamber; and
a gas supply unit that supplies a processing gas into the chamber, the processing gas including tungsten and a component for etching a material including silicon;
a radio-frequency power supply that supplies a source radio-frequency power for generating plasma from the processing gas in the chamber;
a bias power supply electrically coupled to the substrate support unit; and
a control unit,
wherein in a state where the substrate is disposed on the substrate support unit, the control unit controls the gas supply unit, the radio-frequency power supply, and the bias power supply to perform
(b) supplying the processing gas from the gas supply unit into the chamber, and
(c) repeating a cycle while (b) is being performed,
wherein the cycle includes
   (c1) setting a power level of the source radio-frequency power to a level L_{S1}, and a level of an electrical bias supplied from the bias power supply to the substrate support unit to a level L_{B1},
   (c2) after (c1), setting the power level of the source radio-frequency power to a level L_{S2}, and the level of the electrical bias to a level L_{B2}, and
   (c3) after (c2), setting the power level of the source radio-frequency power to a level L_{S3}, and the level of the electrical bias to a level L_{B3},
wherein the level L_{S1} is higher than the levels L_{S2} and L_{S3},
wherein the level L_{B3} is higher than the level L_{B1}, and
wherein the level L_{B2} is higher than zero.

According to an embodiment, it is possible to provide a technology of improving the etching selectivity.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing method comprising:
(a) providing a substrate on a substrate support in a chamber of a plasma processing apparatus, the substrate including a first region formed of a material including silicon and a second region formed of a material different from the material of the first region;
(b) supplying a processing gas into the chamber, the processing gas including tungsten and a component for etching the first region; and
(c) repeating a cycle while (b) is being performed,
wherein the cycle includes
(c1) setting a power level of a source radio-frequency power for generating plasma from the processing gas in the chamber to a level L_{S1}, and a level of an electrical bias supplied to the substrate support to a level L_{B1},
(c2) after (c1), setting the power level of the source radio-frequency power to a level L_{S2}, and the level of the electrical bias to a level L_{B2}, and
(c3) after (c2), setting the power level of the source radio-frequency power to a level L_{S3}, and the level of the electrical bias to a level L_{B3},
wherein the level L_{S1} is higher than the levels L_{S2} and L_{S3},
wherein the level L_{B3} is higher than the level L_{B1}, and
wherein the level L_{B2} is higher than zero.

2. The substrate processing method according to claim 1, wherein the level L_{S2} is higher than zero.

3. The substrate processing method according to claim 1, wherein the level L_{S3} is substantially zero.

4. The substrate processing method according to claim 1, wherein the level L_{B2} is lower than the level L_{B3}.

5. The substrate processing method according to claim 1, wherein the level L_{B1} is substantially zero.

6. The substrate processing method according to claim 1, wherein in the cycle, a time length of (c3) is longer than a time length of (c2).

7. The substrate processing method according to claim 1, wherein the processing gas includes tungsten halide gas or tungsten hexafluoride gas.

8. The substrate processing method according to claim 7, wherein the processing gas further includes at least one of a fluorine-containing gas, an oxygen-containing gas, and a hydrogen-containing gas.

9. The substrate processing method according to claim 1, wherein the material of the first region is silicon oxide.

10. The substrate processing method according to claim 9, wherein the material of the second region is silicon nitride, silicon germanium, tungsten carbide, or silicon carbide.

11. The substrate processing method according to claim 1, wherein
the cycle further includes
(c4) after (c3), setting the power level of the source radio-frequency power and the level of the electrical bias to substantially zero.

12. A plasma processing apparatus comprising:
a chamber;
a substrate support provided in the chamber and configured to accommodate a substrate; and
a gas supply configured to supply a processing gas into the chamber;
a radio-frequency power supply configured to supply a source radio-frequency power for generating plasma from the processing gas in the chamber;
a bias power supply electrically coupled to the substrate support; and
a controller,
wherein in a state where the substrate is disposed on the substrate support, the controller controls the gas supply, the radio-frequency power supply, and the bias power supply to perform a series of process including
(b) supplying the processing gas from the gas supply into the chamber, the processing gas including tungsten and a component for etching a material including silicon, and
(c) repeating a cycle while (b) is being performed,
wherein the cycle includes
(c1) setting a power level of the source radio-frequency power to a level L_{S1}, and a level of an electrical bias supplied from the bias power supply to the substrate support to a level L_{B1},
(c2) after (c1), setting the power level of the source radio-frequency power to a level L_{S2}, and the level of the electrical bias to a level L_{B2}, and
(c3) after (c2), setting the power level of the source radio-frequency power to a level L_{S3}, and the level of the electrical bias to a level L_{B3},
wherein the level L_{S1} is higher than the levels L_{S2} and L_{S3},
wherein the level L_{B3} is higher than the level L_{B1}, and
wherein the level L_{B2} is higher than zero.
